(19) United States
(12) Patent Application Publication
(10) Pub. No.: US 2026/0324094 A1
(43) Pub. Date: Oct. 15, 2026

(54) QUANTUM DOT TANDEM SOLAR CELL AND PREPARATION METHOD THEREOF

(71) Applicant: DEZHOU UNIVERSITY, Dezhou (CN)

(72) Inventors: Yijun GAO, Dezhou (CN); Huimin ZHANG, Dezhou (CN); Xiaolei ZHANG, Dezhou (CN); Chao CHEN, Dezhou (CN); Xiuyun SUN, Dezhou (CN); Jie CHEN, Dezhou (CN); Fang WANG, Dezhou (CN); Min LI, Dezhou (CN)

(73) Assignee: DEZHOU UNIVERSITY, Dezhou (CN)

(21) Appl. No.: 19/108,452

(22) PCT Filed: Oct. 18, 2022
(86) PCT No.: PCT/CN2022/125940

§ 371 Date: Mar. 4, 2025

(30) Foreign Application Priority Data
Sep. 7, 2022 (CN) 202211098827.1

(51) Int. Cl. H10F 10/161; H10F 71/00; H10F 77/14; H10F 77/169; H10F 77/20

(52) U.S. Cl. CPC H10F 10/161; H10F 71/138; H10F 77/1433; H10F 77/1696; H10F 77/247

(57) ABSTRACT

Provided are a quantum dot tandem solar cell and a preparation method thereof. The quantum dot tandem solar cell includes a front cell, a transparent conductive middle layer, a rear cell, and a counter electrode. The front cell includes a conductive substrate, a first oxide semiconductor film, and a first semiconductor quantum dot film. The transparent conductive middle layer is an indium tin oxide (ITO) film. The rear cell includes a second oxide semiconductor film and a second semiconductor quantum dot film. The counter electrode is a metal electrode.

### CROSS-REFERENCE TO THE RELATED APPLICATIONS

This application is the national phase entry of International Application No. PCT/CN2022/125940, filed on Oct. 18, 2022, which is based upon and claims priority to Chinese Patent Application No. 202211098827.1, filed on Sep. 7, 2022, the entire contents of which are incorporated herein by reference.

### TECHNICAL FIELD

The present disclosure relates to the technical field of photovoltaic devices, and in particular to a quantum dot tandem solar cell and a preparation method thereof.

### BACKGROUND

Photovoltaic devices are semiconductor devices that absorb sunlight and convert the absorbed sunlight into electricity. The solar spectrum is a hybrid spectrum. Each specific semiconductor material can only absorb light with a wavelength greater than a specific wavelength. In a single cell, the unabsorbed sunlight is lost in the form of transmitted light or heat energy, and thus cannot be utilized. Moreover, after being absorbed, the high-energy light undergoes a heat loss due to band gaps. Due to the low-energy light transmission loss and the high-energy photothermal loss, the efficiency of a single cell cannot exceed 33.4%, known as the Shockley-Queisser limit.

In tandem cells, two single cells with different band gaps are combined, where a cell with a large band gap is arranged as a front cell to absorb high-energy light and a cell with a small band gap is arranged as a rear cell to absorb low-energy light, thereby reducing the energy loss and improves the efficiency of light energy utilization.

Quantum dots are semiconductor nanostructures that confine excitons in three spatial dimensions. Quantum dots are generally spherical or spherical-like, with a diameter of 2 nm to 20 nm. Quantum dots are important low-dimensional semiconductor materials. Common quantum dots are composed of IV, II-VI, IV-VI, or III-V elements. Quantum dots exhibit characteristics such as broad and continuously-distributed excitation spectra, narrow and symmetrical emission spectra, tunable emission colors, high photochemical stability, and long fluorescence lifetime. Thus, quantum dots have been widely used in a variety of optoelectronic devices including tandem cells.

However, although there have been some reports on quantum dot tandem solar cells, the existing quantum dot tandem solar cells still suffer from low photoelectric conversion efficiency. Therefore, there is an urgent need to develop a quantum dot tandem solar cell with high photoelectric conversion efficiency.

### SUMMARY

In order to solve the above-mentioned technical problems, the present disclosure provides a quantum dot tandem solar cell, including a front cell, a transparent conductive middle layer, a rear cell, and a counter electrode, where
the front cell includes a conductive substrate, a first oxide semiconductor film, and a first semiconductor quantum dot film;
the transparent conductive middle layer is an indium tin oxide (ITO) film; and
the rear cell includes a second oxide semiconductor film and a second semiconductor quantum dot film.

In some embodiments, the first oxide semiconductor film and the second oxide semiconductor film independently are a ZnO nanoparticle film; and the first semiconductor quantum dot film and the second semiconductor quantum dot film independently are a quantum dot-lead halide composite film.

In some embodiments, the quantum dot-lead halide composite film is a PbS quantum dot-lead halide composite film.

In some embodiments, the counter electrode is a metal electrode; and the conductive substrate is a conductive glass.

The present disclosure also provides a method for preparing a quantum dot tandem solar cell, including:
step S1, applying a first oxide semiconductor material, a first quantum dot, and a first lead halide in sequence onto an upper surface of a conductive substrate to obtain a front cell;
step S2, applying a transparent conductive middle layer material onto the front cell obtained in step S1 to obtain a front cell covered with a transparent conductive middle layer;
step S3, applying a second oxide semiconductor material, a second quantum dot, and a second lead halide in sequence onto a surface of the transparent conductive middle layer obtained in S2 to obtain a front cell-transparent conductive middle layer-rear cell complex, and
step S4, depositing a metal electrode on a surface of a rear cell in the front cell-transparent conductive middle layer-rear cell complex to obtain the quantum dot tandem solar cell.

In some embodiments, the first oxide semiconductor material and the second oxide semiconductor material independently are ZnO nanoparticles; the first quantum dot and the second quantum dot independently are a PbS quantum dot; the first lead halide and the second lead halide independently are lead iodide; and the transparent conductive middle layer material is ITO.

In some embodiments, in step S1, step S2, and step S3, the applying is conducted by spin-coating at a rotational speed of 2,000 rpm/min for 120 seconds.

In some embodiments, in step S2, applying the transparent conductive middle layer material is conducted in an Ar gas environment under a 1.5 mTorr pressure.

In some embodiments, in step S4, the metal electrode is deposited at a speed of 0.1 nm/s.

In some embodiments, in step S4, the metal electrode is a gold electrode with a thickness of 100 nm.

Compared with the prior art, some embodiments of the present disclosure have the following beneficial effects:

The present disclosure provides a quantum dot tandem solar cell and a preparation method thereof. The quantum dot tandem solar cell specifically includes a front cell, a transparent conductive middle layer, a rear cell, and a counter electrode. The front cell includes a conductive substrate, a first oxide semiconductor film, and a first semiconductor quantum dot film. The transparent conductive middle layer is an ITO film. The rear cell includes a second oxide semiconductor film and a second semiconductor quantum dot film. The counter electrode is a metal electrode. The quantum dot tandem solar cell prepared by the present disclosure adopts a highly-transparent ITO middle layer, which greatly improves the efficiency of light energy utilization of the solar cell and effectively improves the photoelectric conversion efficiency of the cell.

### BRIEF DESCRIPTION OF THE DRAWINGS

FIG. 1 shows cell efficiency testing results of PbS quantum dot tandem solar cells prepared in Examples 1 to 5 of the present disclosure;

FIG. 2 shows cell efficiency testing results of PbS quantum dot tandem solar cells prepared in Example 3 and Comparative Example 1 of the present disclosure; and

FIG. 3 shows a schematic diagram of the structure of the PbS quantum dot tandem solar cell according to an embodiment of the present disclosure.

### DETAILED DESCRIPTION OF THE EMBODIMENTS

The technical solutions in the embodiments of the present disclosure will be clearly and completely described below. Apparently, the described embodiments are merely some rather than all of the embodiments of the present disclosure. All other embodiments obtained by those of ordinary skill in the art based on the embodiments of the present disclosure without inventive efforts shall fall within the scope of the present disclosure.

### Example 1

PbS quantum dots are semiconductor nanocrystals generally with a diameter of less than 40 nm. Due to the large Bohr exciton radius ratio of the PbS material itself, it is easy to produce a quantum confinement effect, the splitting of an energy level, and a band gap. Moreover, the size of a PbS nanocrystal could be controlled to regulate the size of a band gap. If the diameter of a nanocrystal is reduced, the band gap would be enlarged. If the diameter of the nanocrystal increases, the band gap would be narrowed. This characteristic of quantum dots facilitates the selection of materials for tandem cells. This example disclosed a method for preparing a PbS quantum dot tandem solar cell, which was performed as follows:

### S1: Preparation of a Front Cell

S1-1: An ITO glass as a conductive substrate was ultrasonically cleaned with a detergent, water, ethanol, and acetone in sequence for 30 min in each liquid.

S1-2: ZnO nanoparticles were spin-coated onto a resulting cleaned ITO glass at a spin-coating speed of 2,000 rpm for 120 s by using a spin-coating machine to obtain a ZnO film.

S1-3: A PbS quantum dot with a band gap of 1.5 eV was spin-coated onto the ZnO film at a spin-coating speed of 2,000 rpm/min for 120 s to obtain a semi-finished cell product. Then the semi-finished cell product was immediately soaked in a solution of Pbl in N, N-dimethylformamide (DMF) with a concentration of 4.6 mg/mL, then washed with acetonitrile, and then air-dried to obtain the front cell.

### S2: Preparation of a Transparent Conductive Middle Layer on the Front Cell:

In an Ar gas environment and under a 1.5 mTorr pressure, an ITO film with a thickness of 20 nm was formed on the front cell obtained in S1 through magnetron sputtering to obtain the transparent conductive middle layer.

### S3: Preparation of a Front Cell-Transparent Conductive Middle Layer-Rear Cell Complex:

S3-1: ZnO nanoparticles were spin-coated onto the transparent conductive middle layer obtained in S2 by using a spin-coating machine at a spin-coating speed of 2,000 rpm/min for 120 s to obtain a ZnO film.

S3-2: A PbS quantum dot with a band gap of 1.2 eV was spin-coated onto the ZnO film at a spin-coating speed of 2,000 rpm/min for 120 s to obtain a semi-finished cell product. The semi-finished cell product was immediately soaked in a solution of Pblz in DMF with a concentration of 4.6 mg/mL, washed with acetonitrile, and then air-dried to obtain the front cell-transparent conductive middle layer-rear cell complex.

### S4: Preparation of a Counter Electrode on the Front Cell-Transparent Conductive Middle Layer-Rear Cell Complex:

A gold electrode layer with a thickness of 100 nm was vacuum-deposited at a speed of 0.1 nm/s on a surface of a rear cell in the front cell-transparent conductive middle layer-rear cell complex to obtain the PbS quantum dot tandem solar cell.

### Example 2

This example disclosed a method for preparing a PbS quantum dot tandem solar cell. The method in this example was the same as the method in Example 1, except that, in S2, an ITO film with a thickness of 80 nm was formed on the front cell through magnetron sputtering.

### Example 3

This example disclosed a method for preparing a PbS quantum dot tandem solar cell. The method in this example was the same as the method in Example 1, except that, in S2, an ITO film with a thickness of 100 nm was formed on the front cell through magnetron sputtering.

### Example 4

This example disclosed a method for preparing a PbS quantum dot tandem solar cell. The method in this example was the same as the method in Example 1, except that, in S2, an ITO film with a thickness of 140 nm was formed on the front cell through magnetron sputtering.

### Example 5

This example disclosed a method for preparing a PbS quantum dot tandem solar cell. The method in this example was the same as the method in Example 1, except that, in S2, an ITO film with a thickness of 200 nm was formed on the front cell through magnetron sputtering.

### Comparative Example 1

This example disclosed a method for preparing a PbS quantum dot tandem solar cell. The method in this example was the same as the method in Example 3, except that, in S3-2, a PbS quantum dot with a band gap of 1.5 eV was spin-coated on the ZnO film.

### Test Example 1

The PbS quantum dot tandem solar cells prepared in Examples 1 to 5 and Comparative Example 1 each were tested for a cell efficiency.

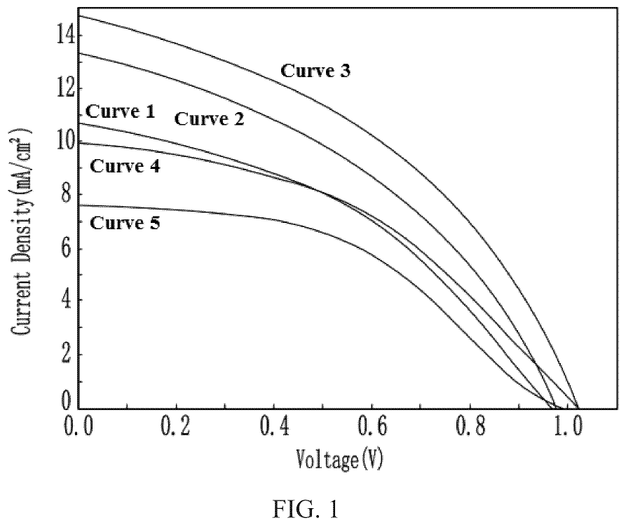

FIG. 1 shows IV curves of cells with ITO middle layers of different thicknesses. An IV curve 1 shows a cell efficiency corresponding to an ITO middle layer with a thickness of 20 nm, and the cell efficiency is 4.2%. An IV curve 2 shows a cell efficiency corresponding to an ITO middle layer with a thickness of 80 nm, and the cell efficiency is 5.2%. An IV curve 3 shows a cell efficiency corresponding to an ITO middle layer with a thickness of 100 nm, and the cell efficiency is 6.2%. An IV curve 4 shows a cell efficiency corresponding to an ITO middle layer with a thickness of 1,400 nm, and the cell efficiency is 4.3%. An IV curve 5 shows a cell efficiency corresponding to an ITO middle layer with a thickness of 200 nm, and the cell efficiency is 3.4%. It can be seen from the curves in FIG. 1 that the optimal ITO thickness is 100 nm, which leads to the optimal cell efficiency.

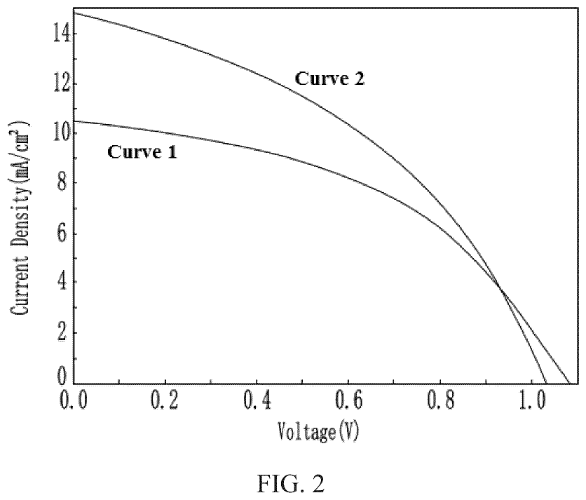

FIG. 2 shows cell efficiency testing results of Example 3 and Comparative Example 1. Specifically, FIG. 2 shows the comparison of IV curves of a cell with a single band gap and a cell with a large-small band gap combination. A curve 1 is an IV curve of the cell with the same band gap in Comparative Example I (band gaps of the front and rear cells both are 1.5 eV), and the corresponding efficiency is 5.1%. A curve 2 is an IV curve of the cell with a large-small band gap combination in Example 3 (the front cell has a band gap of 1.5 eV and the rear cell has a band gap of 1.2 eV), and the corresponding efficiency is 6.2%.

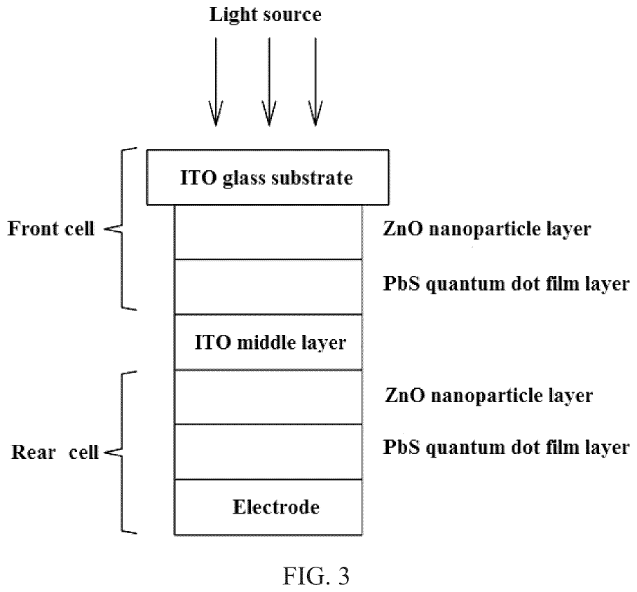

FIG. 3 shows a schematic diagram of the structure of the PbS quantum dot tandem solar cell.

The above are merely preferred embodiments of the present disclosure. It should be noted that a person of ordinary skill in the art may further make several modifications and substitutions without departing from the technical principle of the present disclosure, but such modifications and substitutions should be deemed as falling within the scope of the present disclosure.

What is claimed is:

1. A quantum dot tandem solar cell, comprising a front cell, a transparent conductive middle layer, a rear cell, and a counter electrode, wherein the front cell comprises a conductive substrate, a first oxide semiconductor film, and a first semiconductor quantum dot film;
the transparent conductive middle layer is an indium tin oxide (ITO) film; and
the rear cell comprises a second oxide semiconductor film and a second semiconductor quantum dot film.

2. The quantum dot tandem solar cell according to claim 1, wherein the first oxide semiconductor film and the second oxide semiconductor film independently are a ZnO nanoparticle film; and the first semiconductor quantum dot film and the second semiconductor quantum dot film independently are a quantum dot-lead halide composite film.

3. The quantum dot tandem solar cell according to claim 2, wherein the quantum dot-lead halide composite film is a PbS quantum dot-lead halide composite film.

4. The quantum dot tandem solar cell according to claim 1, wherein the counter electrode is a metal electrode; and the conductive substrate is a conductive glass.

5. A method for preparing a quantum dot tandem solar cell, comprising:
step S1, applying a first oxide semiconductor material, a first quantum dot, and a first lead halide in sequence onto an upper surface of a conductive substrate to obtain a front cell;
step S2, applying a transparent conductive middle layer material onto the front cell obtained in step S1 to obtain a front cell covered with a transparent conductive middle layer;
step S3, applying a second oxide semiconductor material, a second quantum dot, and a second lead halide in sequence onto a surface of the transparent conductive middle layer obtained in step S2 to obtain a front cell-transparent conductive middle layer-rear cell complex; and
step S4, depositing a metal electrode on a surface of a rear cell in the front cell-transparent conductive middle layer-rear cell complex to obtain the quantum dot tandem solar cell.

6. The method according to claim 5, wherein the first oxide semiconductor material and the second oxide semiconductor material independently are ZnO nanoparticles, the first quantum dot and the second quantum dot independently are a PbS quantum dot; the first lead halide and the second lead halide independently are lead iodide; and the transparent conductive middle layer material is ITO.

7. The method according to claim 5, wherein in step S1, step S2, and step S3, the applying is conducted by spin-coating at a rotational speed of 2,000 rpm/min for 120 seconds.

8. The method according to claim 5, wherein in step S2, the applying the transparent conductive middle layer material is conducted in an Ar gas environment under a 1.5 mTorr (millitorr) pressure.

9. The method according to claim 5, wherein in step S4, the metal electrode is deposited at a speed of 0.1 nm/s.

10. The method according to claim 5, wherein in step S4, the metal electrode is a gold electrode with a thickness of 100 nm.

11. The method according to claim 9, wherein in step S4, the metal electrode is a gold electrode with a thickness of 100 nm.
